(19) United States
(12) Patent Application Publication
(10) Pub. No.: US 2008/0259570 A1
(43) Pub. Date: Oct. 23, 2008

(54) TRANSMITTING DEVICE AND ELECTRONIC APPARATUS USING THE SAME

(76) Inventor: Hiroki Iwamiya, Osaka (JP)

Correspondence Address: MCDERMOTT WILL & EMERY LLP, 600 13TH STREET, NW, WASHINGTON, DC, 20005-3096, US

(21) Appl. No.: 12/102,367

(22) Filed: Apr. 14, 2008

(30) Foreign Application Priority Data
Apr. 17, 2007 (JP) 2007-107938

(51) Int. Cl. H05K 7/20

(52) U.S. Cl. 361/707

(57) ABSTRACT

A transmitting device includes (a) an amplifier mounted on the top face or the internal layer of a substrate, (b) a semiconductor integrated circuit mounted on the bottom face of the substrate and connected to the amplifier, and (c) a spacer substrate disposed on the bottom face of the substrate. The spacer substrate is disposed at least under the amplifier. This structure allows the heat generated from the amplifier to be efficiently dissipated through the spacer substrate, thus inhibiting deterioration of the characteristics of the amplifier caused by the heat.

### BACKGROUND OF THE INVENTION

1. Field of the Invention

The present invention relates to a transmitting device for use in radio communications, such as local area network (LAN) communications and metropolitan area network (MAN) communications, and to an electronic apparatus using the transmitting device.

2. Background Art

A description is provided of a conventional transmitting device, with reference to FIG. 5. The drawing shown in the upper left portion of FIG. 5 is an exploded perspective view of a substrate in the conventional transmitting device. The drawing shown in the lower right portion of FIG. 5 is an exploded perspective view of a spacer substrate and a semiconductor integrated circuit (IC) in the conventional transmitting device. With reference to FIG. 5, conventional transmitting device 1 includes the following elements: substrate 2; semiconductor integrated circuit (IC) 4 disposed on the bottom face of substrate 2 and generating a transmission signal; spacer substrate 5 having a height larger than the height of semiconductor IC 4; radio-frequency (RF) semiconductor circuit 9 disposed on the top face of substrate 2 and connected to the output side of semiconductor IC 4; amplifier 3 connected to the output side of RF semiconductor circuit 9; and oscillating circuit 10 connected to RF semiconductor circuit 9 and generating a reference signal for the transmission signal. The bottom face of spacer substrate 5 is mounted on a motherboard (not shown), for example.

In conventional transmitting device 1 as described above, spacer substrate 5 is not disposed under amplifier 3 or only a part of spacer substrate 5 is disposed under amplifier 3. Such disposition makes a space between amplifier 3 and the motherboard (not shown). This space hinders amplifier 3 from sufficiently dissipating heat to the motherboard (not shown). Thus, the heat generated from amplifier 3 can increase the capacity of amplifier 3, thus decreasing the gain of amplifier 3.

For example, Patent Document 1 is known as information about conventional arts related to this invention.

### [Patent Document 1] Japanese Patent Unexamined Publication No. 2006-73673

### SUMMARY OF THE INVENTION

A transmitting device includes the following elements: a substrate; an amplifier mounted on the top face or the internal layer of the substrate; a semiconductor integrated circuit (IC) mounted on the bottom face of the substrate and connected to the amplifier; and a spacer substrate disposed on the bottom face of the substrate. The height of the spacer substrate is larger than the height of the semiconductor IC. The spacer substrate is disposed at least under the amplifier.

In the above structure, the heat generated from the amplifier can efficiently be dissipated through the spacer substrate disposed on the bottom face of the substrate. This efficient heat dissipation can inhibit deterioration of the characteristics of the amplifier.

### BRIEF DESCRIPTION OF THE DRAWINGS

FIG. 1 is an exploded perspective view of a transmitting device in accordance with a first exemplary embodiment of the present invention.

FIG. 2 is an exploded perspective view of a transmitting device in accordance with a second exemplary embodiment and a third exemplary embodiment of the present invention.

FIG. 3 is an exploded perspective view of a transmitting device in accordance with a fourth exemplary embodiment of the present invention.

FIG. 4 is an exploded perspective view of a transmitting device and an electronic apparatus in accordance with a fifth exemplary embodiment of the present invention.

FIG. 5 is an exploded perspective view of a conventional transmitting device.

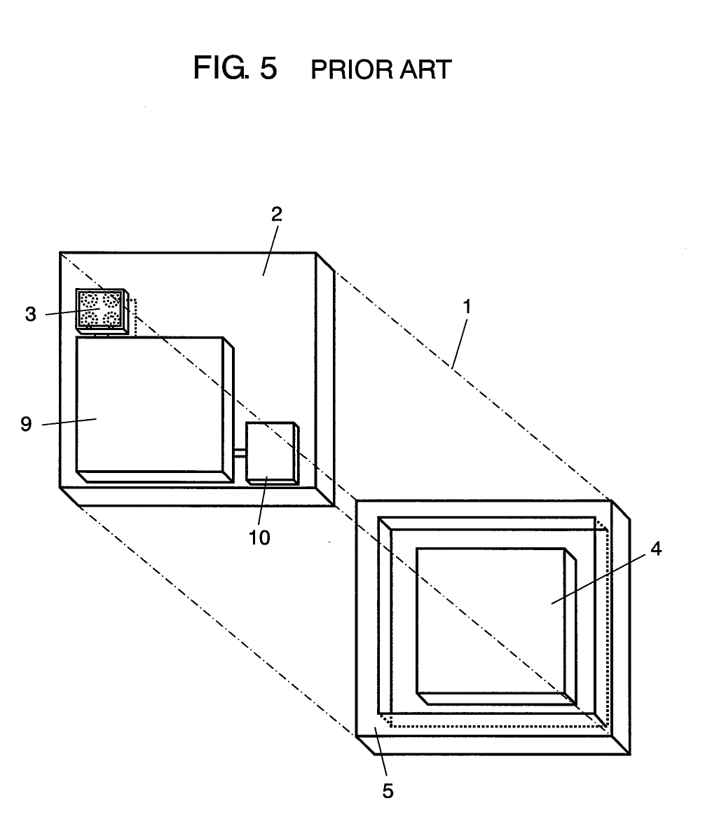

### DETAILED DESCRIPTION OF THE INVENTION

### First Embodiment

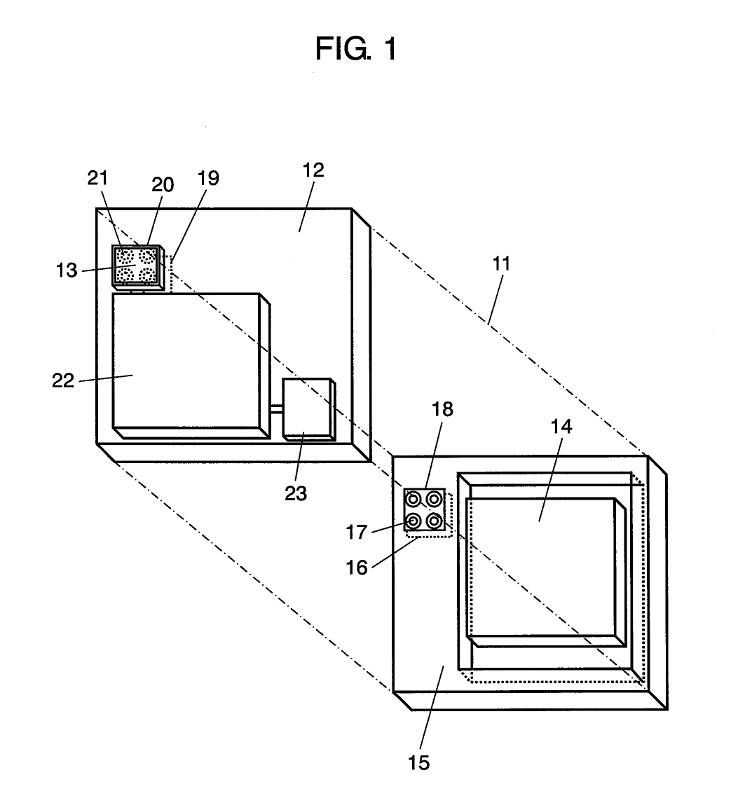

Hereinafter, a description is provided of the first exemplary embodiment of the present invention, with reference to FIG. 1. FIG. 1 is an exploded perspective view of a transmitting device in accordance with the first exemplary embodiment of the present invention, as seen from the top face thereof. The upper left portion of FIG. 1 shows an exploded perspective view of main substrate 12. The lower right portion of FIG. 1 shows an exploded perspective view of spacer substrate 15 and semiconductor integrated circuit (IC) 14 both disposed directly under main substrate 12. With reference to FIG. 1, transmitting device 11 is of the chip type, and is connected to an electronic apparatus (not shown), such as a personal computer and a portable telephone, and used for radio communications, such as LAN communications and MAN communications.

Transmitting device 11 includes the following elements: substrate 12; amplifier 13 mounted on the top face or the internal layer of main substrate 12; semiconductor integrated circuit (IC) 14 mounted on the bottom face of main substrate 12 and connected to amplifier 13; and spacer substrate 15 disposed on the bottom face of main substrate 12.

Main substrate 12 has a rectangular shape, and is a multilayer substrate having a thickness equal to or smaller than 0.5 mm and made of a resin, such as glass epoxy. Amplifier 13 is made of an integrated circuit, and amplifies a transmission signal supplied from semiconductor IC 14 to a desired output level.

The outside shape of spacer substrate 15 is like a rectangular frame having the same size as main substrate 12. The height (thickness) of spacer 15 is larger than the height (thickness) of semiconductor IC 14. The bottom face of spacer substrate 15 is mounted on the motherboard (not shown) of an electronic apparatus, such as a personal computer and a portable telephone.

Spacer substrate 15 allows transmitting device 11 to be a chip-type component that is surface-mountable on a motherboard (not shown), although the transmitting device is a double-sided mounting device having elements mounted on the top face and bottom face of main substrate 12 thereof.

In the four sides of the rectangular frame of spacer substrate 15, at least one side is wider than the other sides. This wider portion is disposed directly under amplifier 13. In the above structure, the heat generated from amplifier 13 can efficiently be dissipated through spacer substrate 15 disposed on the bottom face of main substrate 12. This efficient heat dissipation can inhibit deterioration of the characteristics of amplifier 13 caused by the heat.

In the wider side of spacer substrate 15, first ground pattern 16 is disposed under amplifier 13. Further, in order to provide electrical continuity between amplifier 13 and first ground pattern 16 through first through-hole 17, second ground pattern 18 is disposed on the top face of spacer substrate 15.

Main substrate 12 includes third ground pattern 19 disposed on the bottom face of main substrate 12 under amplifier 13. Third ground pattern 19 is electrically connected with second ground pattern 18 disposed on the top face of spacer substrate 15 by soldering spacer substrate 15 and main substrate 12 together. Further, main substrate 12 includes fourth ground pattern 20 that is disposed on the top face of main substrate 12 under amplifier 13 disposed on the top face of main substrate 12. Third ground pattern 19 and fourth ground pattern 20 are in electrical continuity with each other through primary through-hole 21.

In the above structure, spacer substrate 15 is disposed on the bottom face of main substrate 12, particularly under amplifier 13. Thus, a large area of third ground pattern 19 disposed on the bottom face of main substrate 12 can be secured without being hindered by the wiring of semiconductor IC 14.

The heat generated from amplifier 13 is transferred from fourth ground pattern 20 disposed on the top face of main substrate 12 to third ground pattern 19 disposed on the bottom face of main substrate 12 through primary through-hole 21. Further, third ground pattern 19 and second ground pattern 18 are electrically connected with each other by soldering, and this metal-to-metal contact improves heat conductivity. Then, this heat is transferred from second ground pattern 18 disposed on the top face of spacer substrate 15 to first ground pattern 16 through first through-hole 17. By this heat transfer, the heat generated from amplifier 13 can efficiently be dissipated from main substrate 12 through spacer substrate 15. This heat dissipation can inhibit deterioration of the characteristics of amplifier 13 caused by the heat. Further, spacer substrate 15 is mounted on a motherboard (not shown) closely contacted therewith. This contact allows the heat to escape from first ground pattern 16 to the motherboard, thus further improving heat dissipation.

Semiconductor IC 14 may be structured as two chips by separating the RF part from the base-band part, like RF semiconductor circuit 22 disposed on the top face of main substrate 12 as shown in FIG. 1. Oscillating circuit 23 for generating a reference signal for the transmission signal may be disposed on the top face or bottom face of main substrate 12.

Further, preferably, the diameter of first through-hole 17 is designed to be larger than the diameter of primary through-hole 21. The size of primary through-hole 21 is restricted by the shape and size of the terminal part of amplifier 13 and thus is difficult to be enlarged in many cases. However, first through-hole 17 have fewer restrictions imposed on the shape thereof, and can be enlarged. A larger through-hole can provide the larger heat conduction. This structure can improve the heat conduction efficiency of first through-hole 17, thus further inhibiting deterioration of the characteristics of amplifier 13 caused by the heat. The communication device of this exemplary embodiment has an extremely advantageous structure in attaining such a structure. Because main substrate 12 and spacer substrate 15 are formed of separate pieces as shown in FIG. 1, main substrate 12 and spacer substrate 15 can have different design rules. Thus, a design rule for forming fine conductor patterns and fine through-holes is applicable to main substrate 12 on which components, such as semiconductor IC 14 and RF semiconductor circuit 22, are to be mounted. A design rule for forming through-holes having a large diameter is applicable to spacer substrate 15 on which components, such as RF semiconductor circuit 22, are not to be mounted. In this manner, the diameter of first through-hole 17 to be formed through spacer substrate 15 can be designed larger than the diameter of primary through-hole 21 to be formed through main substrate 12 by making full use of the structural feature of the communication device of the present invention, i.e. main substrate 12 and spacer substrate 15 formed of separate pieces. Thus, the heat generated in amplifier 13 can be dissipated efficiently.

At least one of first ground pattern 16 and second ground pattern 18 may be designed to have an area larger than the area of fourth ground pattern 20. This structure can improve the heat dissipation effect of first ground pattern 16 and second ground pattern 18. Thus, the heat generated in amplifier 13 can be dissipated efficiently. For the same reason as described above, the communication device of this exemplary embodiment has an extremely advantageous structure in attaining such a structure.

Further, spacer substrate 15 may be implemented by a large number of divided pieces of substrate 15. In such a structure, a substrate material having high heat dissipation efficiency may be used only for some of the pieces of substrate 15 disposed under amplifier 13. Thus, the substrate material that has high heat dissipation efficiency but relatively high cost and poor workability can be used in the necessary part only. As a result, an inexpensive and easily produced transmitting device having high heat dissipation efficiency can be provided.

### Second Embodiment

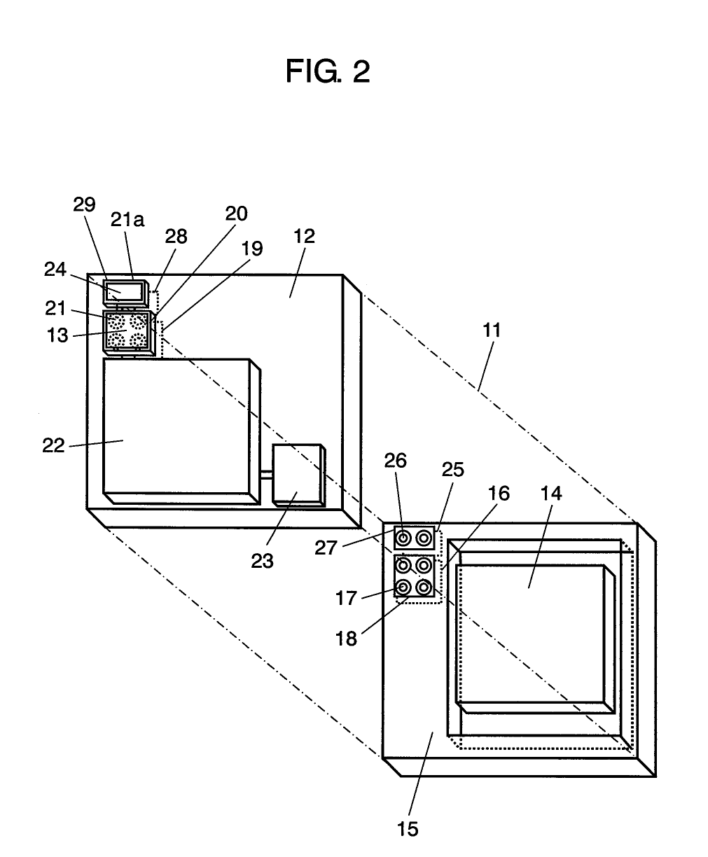

Hereinafter, a description is provided of the second exemplary embodiment of the present invention, with reference to FIG. 2. FIG. 2 is an exploded perspective view of a transmitting device in accordance with the second exemplary embodiment of the present invention. Elements similar to those in the first embodiment have the same reference marks. The descriptions of those elements are omitted, and differences are detailed.

The upper left portion of FIG. 2 shows main substrate 12 in the transmitting device of the second exemplary embodiment. The lower right portion of FIG. 2 shows spacer substrate 15 and semiconductor integrated circuit (IC) 14 both disposed directly under main substrate 12. With reference to FIG. 2, transmitting device 11 includes semiconductor switch 24 disposed on the top face of main substrate 12 and connected to amplifier 13. At least under semiconductor switch 24, spacer substrate 15 is disposed. Spacer substrate 15 includes fifth ground pattern 25 disposed on the bottom face of spacer substrate 15 under semiconductor switch 24. First ground pattern 16 and fifth ground pattern 25 are disposed on spacer substrate 15 so as to be electrically insulated from each other. Further, in order to provide electrical continuity between semiconductor switch 24 and fifth ground pattern 25 through second through-hole 26, sixth ground pattern 27 is disposed on the top face of spacer substrate 15.

Main substrate 12 has seventh ground pattern 28 disposed on the bottom face of main substrate 12 under semiconductor switch 24. Seventh ground pattern 28 is electrically connected with sixth ground pattern 27 disposed on the top face of spacer substrate 15 by soldering spacer substrate 15 and main substrate 12 together.

Further, main substrate 12 has eighth ground pattern 29 that is disposed on the top face of main substrate 12, under semiconductor switch 24 disposed on the top face of main substrate 12. Seventh ground pattern 28 and eighth ground pattern 29 is in electrical continuity with each other through secondary through-hole 21a.

In the above structure, spacer substrate 15 is disposed on the bottom face of main substrate 12 under semiconductor switch 24. Thus, a large area of seventh ground pattern 28 disposed on the bottom face of main substrate 12 can be secured without being hindered by the wiring of semiconductor IC 14.

The loss made when a transmission signal passes through semiconductor switch 24 (passage loss) causes generation of heat from semiconductor switch 24. This heat is transferred from eighth ground pattern 29 disposed on the top face of main substrate 12 to seventh ground pattern 28 disposed on the bottom face of main substrate 12 through secondary through-hole 21a. Further, seventh ground pattern 28 and sixth ground pattern 27 are electrically connected with each other by soldering, and this metal-to-metal contact improves heat conductivity. Then, this heat is transferred from sixth ground pattern 27 disposed on the top face of main substrate 15 to fifth ground pattern 25 through second through-hole 26. By this heat transfer, the heat generated from semiconductor switch 24 can efficiently be dissipated from main substrate 12 through spacer substrate 15. Further, spacer substrate 15 is mounted on a motherboard (not shown) closely contacted therewith. This contact allows the heat to escape from fifth ground pattern 25 to the motherboard, thus further improving heat dissipation.

First ground pattern 16 and fifth ground pattern 25 are electrically insulated from each other on spacer substrate 15. Thus, the influence of the heat generated from amplifier 13 on semiconductor switch 24 can be reduced. Such structures can inhibit deterioration of the characteristics of semiconductor switch 24 caused by the heat.

Further, preferably, the diameter of second through-hole 26 is designed to be larger than the diameter of secondary through-hole 21a. The size of secondary through-hole 21a is restricted by the shape and size of the terminal part of semiconductor switch 24 and thus is difficult to be enlarged in many cases. However, second through-hole 26 have fewer restrictions imposed on the shape thereof, and can be enlarged. A larger through-hole can provide the larger heat conduction. This structure can improve the heat conduction efficiency of second through-hole 26, thus inhibiting deterioration of the characteristics of semiconductor switch 24 caused by the heat. The communication device of this exemplary embodiment has an extremely advantageous structure in attaining such a structure.

Because main substrate 12 and spacer substrate 15 are formed of separate pieces as shown in FIG. 2, main substrate 12 and spacer substrate 15 can have different design rules. Thus, a design rule for forming fine conductor patterns and fine through-holes is applicable to main substrate 12 on which components, such as semiconductor IC 14 and RF semiconductor circuit 22, are to be mounted. A design rule for forming through-holes having a large diameter is applicable to spacer substrate 15 on which micro-components, such as RF semiconductor circuit 22, are not to be mounted. In this manner, the diameter of second through-hole 26 to be formed through spacer substrate 15 can be designed larger than the diameter of secondary through-hole 21a to be formed through main substrate 12 by making full use of the structural feature of the communication device of the present invention, i.e. main substrate 12 and spacer substrate 15 formed of separate pieces. Thus, the heat generated in semiconductor switch 24 can be dissipated efficiently.

At least one of fifth ground pattern 25 and sixth ground pattern 27 may be designed to have an area larger than the area of eighth ground pattern 29. This structure can improve the heat dissipation effect of fifth ground pattern 25 and sixth ground pattern 27. Thus, the heat generated in semiconductor switch 24 can be dissipated efficiently. For the same reason as described above, the communication device of this exemplary embodiment has an extremely advantageous structure in attaining such a structure.

### Third Embodiment

Hereinafter, a description is provided of the third exemplary embodiment of the present invention, with reference to FIG. 2, like the second exemplary embodiment. Elements similar to those in the first and second embodiments have the same reference marks. The descriptions of those elements are omitted, and the descriptions related to the third embodiment are detailed.

With reference to FIG. 2, transmitting device 11 includes radio-frequency (RF) semiconductor circuit 22 disposed on the top face of main substrate 12 and oscillating circuit 23 connected to RF semiconductor circuit 22. Amplifier 13 and oscillating circuit 23 are disposed in positions diagonal to each other on the identical surface of main substrate 12. In other words, the amplifier and the oscillating circuit are spaced at a maximum distance on main substrate 12 having substantially a rectangular shape.

In this manner, amplifier 13 for outputting signals at a large amplitude level and oscillating circuit 23 are spaced from each other so that RF semiconductor circuit 22 is sandwiched therebetween. This disposition can inhibit electromagnetic coupling and interference between amplifier 13 and oscillating circuit 23, thus preventing deterioration of the characteristics of amplifier 13 and oscillating circuit 23. Amplifier 13 and oscillating circuit 23 may be disposed on the opposite faces, i.e. on the top face and bottom face, of main substrate 12 as long as a long distance is secured therebetween.

### Fourth Embodiment

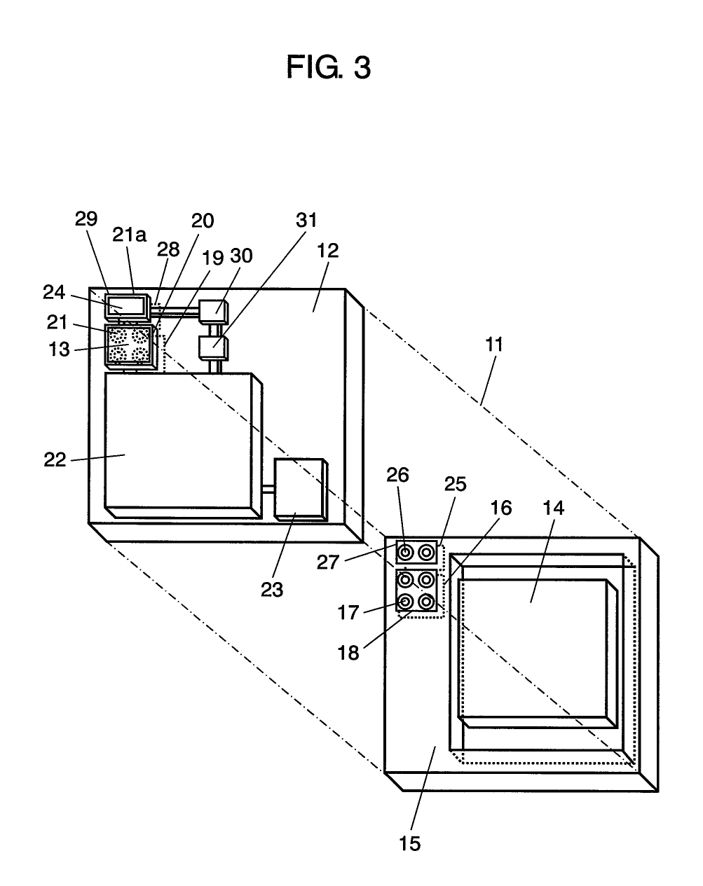

Hereinafter, a description is provided of the fourth exemplary embodiment of the present invention, with reference to FIG. 3. FIG. 3 is an exploded perspective view of a transmitting device in accordance with the fourth exemplary embodiment of the present invention. Elements similar to those in the first to third embodiments have the same reference marks. The descriptions of those elements are omitted, and differences are detailed. The upper left portion of FIG. 3 shows main substrate 12 in transmitting device 11 of the fourth exemplary embodiment. The lower right portion of FIG. 3 shows spacer substrate 15 and semiconductor integrated circuit (IC) 14 in transmitting device 11 of the fourth exemplary embodiment.

Transmitting device 11 of FIG. 3 includes filter 30 for suppressing unnecessary signals and low-noise amplifier 31 that are connected between semiconductor switch 24 and RF semiconductor circuit 22. RF semiconductor circuit 22 has both transmitting function and receiving function. Filter 30 is a band-pass filter made of a chip component. Thus, signals at undesirable frequencies are selectively removed and the transmitting device can be operated together with another system, such as a portable telephone. Low-noise amplifier 31 amplifies minute reception signals. Low-noise amplifier 31 is made of an integrated circuit (IC) or bipolar transistor integrated by a compound semiconductor process, and has the following electrical performance: a gain of at least 10 dB; a noise factor up to 2 dB; and tertiary inter-modulation distortion characteristics of at least −5 dBm. Low-noise amplifier 31 may be incorporated and integrated into semiconductor IC 14 or RF semiconductor circuit 22.

### Fifth Embodiment

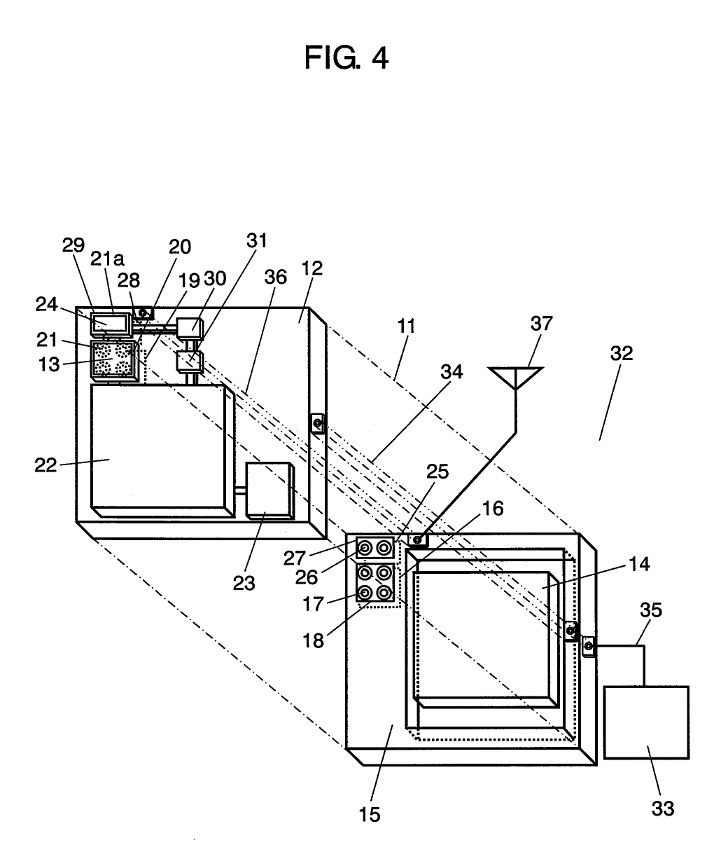

Hereinafter, a description is provided of the fifth exemplary embodiment of the present invention, with reference to FIG. 4. FIG. 4 is an exploded perspective view of a transmitting device and an electronic apparatus in accordance with the fifth exemplary embodiment of the present invention. Elements similar to those in the first to fourth embodiments have the same reference marks. The descriptions of those elements are omitted, and differences are detailed. The upper left portion of FIG. 4 shows main substrate 12 in the transmitting device of the fifth exemplary embodiment. The lower right portion of FIG. 4 shows spacer substrate 15 and semiconductor integrated circuit (IC) 14 in the transmitting device of the fifth exemplary embodiment. Further, the lower right portion shows interface bus 35 and CPU 33 connected thereto. This entire system is referred to as electronic apparatus 32.

With reference to FIG. 4, interface terminal 34 of electronic apparatus 32 is coupled to a microcomputer including CPU 33 via interface bus 35 in conformity with Secure Digital Input Output (SDIO), Serial Peripheral Interface (SPI), or the like. Antenna 37 is connected to antenna terminal 36. In this structure, transmitting device 11 can be controlled by CPU 33 incorporated into electronic apparatus 32. Thus, electronic apparatus 32 that includes transmitting device 11 having improved transmission characteristics as described in the first to fourth exemplary embodiments can be embodied.

Several exemplary embodiments of the present invention have been described with reference to the accompanying drawings. However, the present invention is not limited to these embodiments. It is apparent to those skilled in the art that various changes can be made within the scope of the claims.

In the above description, the respective ground patterns are disposed only on the top face or the bottom face. However, in a multilayer substrate, the ground patterns disposed on an internal layer thereof can offer the same advantages of the present invention. When first ground pattern 16 and fifth ground pattern 25 are disposed on the internal layer, the same advantage of heat dissipation as the above embodiments can be offered.

Amplifier 13 and semiconductor switch 24 may include passive elements provided on an internal layer or a surface layer of main substrate 12, as partial elements thereof. Generally in a multilayer substrate, an inductor component and resistor component can be provided on an internal layer or a surface layer thereof. These passive elements can be used as partial elements of amplifier 13 and semiconductor switch 24. The object of the present invention can be attained, when the invention provides a structure for dissipating heat from positive elements more susceptible to heat than the passive elements using the respective ground patterns and through-holes.

In other words, the present invention includes the following elements: double-sided mounting substrate 12 having an exothermic circuit element (amplifier 13) mounted on the top face thereof; spacer substrate 15 that has a height larger than the maximum height (height of semiconductor IC 14) of circuit elements to be mounted on the bottom face of double-sided mounting substrate 12; and a motherboard closely contacted with spacer substrate 15. Spacer substrate 15 is closely contacted with the bottom face of double-sided mounting substrate 12. Spacer substrate 15 includes an opening space so as not to obstruct the circuit elements to be mounted on the bottom face of double-sided mounting substrate 12, in a position corresponding to the circuit elements. The portion corresponding to the bottom face of the exothermic circuit element is closely contacted with spacer substrate 15. Thus, the exothermic circuit element dissipates heat in the air and also to the spacer substrate closely contacted with the mounting substrate and to a motherboard under the spacer substrate. In order to allow the heat to escape, greater use of metals in through-holes or the like increases heat dissipation efficiency.

### INDUSTRIAL APPLICABILITY

In a transmitting device of the present invention, deterioration of the characteristics of an amplifier caused by heat can be inhibited. Thus, the present invention has an advantage of improving the transmission characteristics of the transmitting device and is useful to a portable terminal or an on-vehicle electronic apparatus.

### REFERENCE MARKS

11 Transmitting device
12 Main substance
13 Amplifier
14 Semiconductor integrated circuit (IC)
15 Spacer substrate
16 First ground pattern
17 First through-hole
18 Second ground pattern
19 Third ground pattern
20 Fourth ground pattern
21 Primary through-hole
21a Secondary through-hole
22 Radio-frequency (RF) semiconductor circuit
23 Oscillating circuit
24 Semiconductor switch
25 Fifth ground pattern
26 Second through-hole
27 Sixth ground pattern
28 Seventh ground pattern
29 Eighth ground pattern
30 Filter
31 Low-noise amplifier
32 Electronic apparatus
33 CPU
34 Interface terminal
35 Interface bus
36 Antenna terminal
37 Antenna

(REFERENCE MARKS)

| | |
|---|---|
| 11 | Transmitting device |
| 12 | Main substrate |
| 13 | Amplifier |
| 14 | Semiconductor integrated circuit (IC) |
| 15 | Spacer substrate |
| 16 | First ground pattern |
| 17 | First through-hole |
| 18 | Second ground pattern |
| 19 | Third ground pattern |
| 20 | Fourth ground pattern |
| 21 | Primary through-hole |
| 21a | Secondary through-hole |
| 22 | Radio-frequency (RF) semiconductor circuit |
| 23 | Oscillating circuit |
| 24 | Semiconductor switch |
| 25 | Fifth ground pattern |
| 26 | Second through-hole |
| 27 | Sixth ground pattern |
| 28 | Seventh ground pattern |
| 29 | Eighth ground pattern |
| 30 | Filter |
| 31 | Low-noise amplifier |
| 32 | Electronic apparatus |
| 33 | CPU |
| 34 | Interface terminal |
| 35 | Interface bus |
| 36 | Antenna terminal |
| 37 | Antenna |

What is claimed is:

1. A transmitting device comprising:
a main substrate;
an amplifier mounted on a top face of the main substrate;
a semiconductor integrated circuit (IC) mounted on a bottom face of the main substrate and coupled to the amplifier; and
a spacer substrate disposed on the bottom face of the main substrate,
wherein a height of the spacer substrate is larger than a height the semiconductor IC, and
the spacer substrate is disposed under the amplifier.

2. The transmitting device of claim 1, wherein the spacer substrate includes a first ground pattern disposed on one of a bottom face and an internal layer of the spacer substrate under the amplifier.

3. The transmitting device of claim 2, wherein the spacer substrate includes a first through-hole, which is electrically coupled to the first ground pattern, under the amplifier.

4. The transmitting device of claim 1, wherein the spacer substrate includes a second ground pattern, which is disposed on a top face of the spacer substrate, under the amplifier.

5. The transmitting device of claim 3, wherein the main substrate includes a third ground pattern, which is disposed on the bottom face of the main substrate, under the amplifier, and the third ground pattern is in electrical continuity with the first ground pattern disposed on a bottom face of the spacer substrate.

6. The transmitting device of claim 1, wherein the main substrate includes a fourth ground pattern, which is disposed on the top face of the main substrate, under the amplifier disposed on the top face of the main substrate.

7. The transmitting device of claim 2, further comprising:
a semiconductor switch disposed on the top face of the main substrate and coupled to the amplifier,
wherein the spacer substrate is disposed under the semiconductor switch, and
the spacer substrate includes a fifth ground pattern disposed on one of a bottom face and an internal layer of the spacer substrate under the semiconductor switch.

8. The transmitting device of claim 7, wherein the first ground pattern and the fifth ground pattern are disposed on the spacer substrate so as to be electrically insulated from each other.

9. The transmitting device of claim 7, wherein the spacer substrate includes a second through-hole, which is electrically coupled to the fifth ground pattern, under the semiconductor switch.

10. The transmitting device of claim 7, wherein the spacer substrate includes a sixth ground pattern, which is disposed on a top face of the spacer substrate, under the semiconductor switch.

11. The transmitting device of claim 7, wherein
the main substrate includes a seventh ground pattern, which is disposed on the bottom face of the main substrate, under the semiconductor switch, and
the seventh ground pattern is in electrical continuity with the fifth ground pattern disposed on the bottom face of the spacer substrate.

12. The transmitting device of claim 7, wherein the main substrate includes an eighth ground pattern, which is disposed under the semiconductor switch disposed on the top face of the main substrate, on the top face of the main substrate.

13. The transmitting device of claim 3, wherein
the main substrate includes a primary through-hole under the amplifier, and
a diameter of the first through-hole is larger than a diameter of the primary through-hole.

14. The transmitting device of claim 9, wherein
the main substrate includes a secondary through-hole under the semiconductor switch, and
a diameter of the second through-hole is larger than a diameter of the secondary through-hole.

15. The transmitting device of claim 6, wherein
the spacer substrate includes:
a first ground pattern, which is disposed on one of a bottom face and an internal layer of the spacer substrate, under the amplifier; and
a second ground pattern, which is disposed on a top face of the spacer substrate, under the amplifier, and
an area of at least one of the first ground pattern and the second ground pattern is larger than an area of the fourth ground pattern.

16. The transmitting device of claim 12, wherein
the spacer substrate includes:
the fifth ground pattern, which is disposed on one of the bottom face and the internal layer of the spacer substrate, under the semiconductor switch; and
a sixth ground pattern, which is disposed on a top face of the spacer substrate, under the semiconductor switch, and
an area of at least one of the fifth ground pattern and the sixth ground pattern is larger than an area of the eighth ground pattern.

17. The transmitting device of claim 1, further comprising:
a radio-frequency (RF) semiconductor circuit disposed on the top face of the main substrate; and
an oscillating circuit coupled to the RF semiconductor circuit,
wherein the amplifier and the oscillating circuit are disposed on an identical surface or different surfaces of the main substrate in positions diagonal to each other.

18. The transmitting device of claim 17, further comprising:
a filter for suppressing an unnecessary signal and a low-noise amplifier that are coupled between the semiconductor switch and the RF semiconductor circuit,
wherein the RF semiconductor circuit has both transmitting function and receiving function.

19. A transmitting device comprising:
a main substrate having a rectangular shape;
an amplifier mounted on a top face of the main substrate;
a semiconductor integrated circuit (IC) mounted on a bottom face of the main substrate and coupled to the amplifier; and
a spacer substrate having a rectangular frame shape and disposed on the bottom face of the main substrate so as to surround the semiconductor IC,
wherein a height of the spacer substrate is larger than a height of the semiconductor IC,
at least one of four sides of the spacer substrate is wider than other sides, and
the amplifier is disposed above the wider side of the spacer substrate.

20. An electronic apparatus comprising:
the transmitting device of claim 1.

21. An electronic apparatus comprising:
a double-sided mounting substrate including an exothermic circuit element mounted on a top face thereof;
a spacer substrate that has a height larger than a maximum height of circuit elements to be mounted on a bottom face of the double-sided mounting substrate; and
a motherboard closely contacted with the spacer substrate,
wherein the spacer substrate is closely contacted with the bottom face of the double-sided mounting substrate,
the spacer substrate includes an opening space in a position corresponding to the circuit elements to be mounted on the bottom face of the double-sided mounting substrate, and
a portion corresponding to a bottom face of the exothermic circuit element is closely contacted with the spacer substrate.
